(19) United States
(12) Patent Application Publication
(10) Pub. No.: US 2014/0299180 A1
(43) Pub. Date: Oct. 9, 2014

(54) MULTI-JUNCTION PHOTOVOLTAIC MODULES INCORPORATING ULTRA-THIN FLEXIBLE GLASS

(71) Applicant: CORNING INCORPORATED, CORNING, NY (US)

(72) Inventors: Mark Francis Krol, Painted Post, NY (US); James Ernest Webb, Corning, NY (US)

(21) Appl. No.: 14/359,171

(22) PCT Filed: Nov. 28, 2012
(86) PCT No.: PCT/US12/66738

§ 371 Date: May 19, 2014

Related U.S. Application Data
(60) Provisional application No. 61/565,080, filed on Nov. 30, 2011.

(51) Int. Cl. H01L 31/048

(52) U.S. Cl. CPC H01L 31/0488
USPC 136/251

(57) ABSTRACT

Multi-junction photovoltaic modules are provided comprising a plurality of photovoltaic structures, a PV encapsulant, a plurality of encapsulating glass layers, and a structural glass layer. The photovoltaic structures define distinct absorption bands and are positioned with the encapsulating glass layers and the structural glass layer. The photovoltaic structures are at least partially surrounded by the PV encapsulant and are separated by respective flexible encapsulating glass layers to electrically isolate adjacent photovoltaic structures and permit the photovoltaic structures to be configured in a parallel or serial PV stacked cell circuit.

This application claims the benefit of priority under 35 U.S.C. §119 of U.S. Provisional Application Ser. No. 61/565080 filed on Nov. 30, 2011 the content of which is relied upon and incorporated herein by reference in its entirety.

### FIELD

The present disclosure relates to photovoltaic (PV) modules.

### BACKGROUND

There is a continuing drive to make PV technology competitive with existing power production methods, e.g., hydro, coal, nuclear, wind, etc., in the power generation industry. To do so, manufacturing costs, conversion efficiency, and efficiency degradation are some of the design challenges that need to be addressed.

### SUMMARY

The present disclosure is directed to the use of thin specialty glass solutions for thin-film single and multi junction PV applications. Specialty glass thickness is typically less than approximately 2 mm, for example, 0.7 mm and can be combined, for example, with a sheet of soda lime glass to complete a module package. It is contemplated that the use of specialty glass will enable higher efficiency thin-film single and multi-junction PV modules because specialty glass typically allows higher temperature deposition of the active device layers, higher optical transmission, and improved device layer in-field durability. As such, it is also contemplated that the concepts of the present disclosure present a path to low cost single and multi-junction PV modules that leverage both the packaging and manufacturing benefits of UltraThin Flexible (UTF) specialty glass.

In addition, embodiments disclosed herein can be utilized for PV module solutions that leverage UTF specialty glass to enable reel-to-reel (RTR) continuous deposition of active device layers. As such, it is contemplated that UTF specialty glass can be used in a RTR configuration to create a low-cost specialty glass package that can be easily integrated into a robust module assembly while maintaining the benefits of using specialty glass.

In accordance with one embodiment of the present disclosure, a multi-junction photovoltaic module comprising a plurality of photovoltaic structures, a PV encapsulant, a plurality of encapsulating glass layers, and a structural glass layer. The photovoltaic structures define distinct absorption bands and are positioned with the encapsulating glass layers and the structural glass layer. The photovoltaic structures are at least partially surrounded by the PV encapsulant and are separated by respective encapsulating glass layers to electrically isolate adjacent photovoltaic structures and permit the photovoltaic structures to be configured in a parallel PV stacked cell circuit. The encapsulating glass layers are less than approximately 2.0 mm in thickness and define a degree of flexibility that is sufficient for non-destructive storage in roll form.

### BRIEF DESCRIPTION OF THE DRAWINGS

The following detailed description of specific embodiments of the present disclosure can be best understood when read in conjunction with the following drawings, where like structure is indicated with like reference numerals and in which:

FIG. 1 is a schematic illustration of a photovoltaic module according to one embodiment of the present disclosure;

FIG. 2 is a schematic illustration of a photovoltaic module manufacturing process according to one embodiment of the present disclosure;

FIG. 3 is a schematic illustration of a photovoltaic module according to an alternative embodiment of the present disclosure;

FIG. 4 is a schematic illustration of a multi-junction photovoltaic module according to the present disclosure;

FIG. 5 illustrates one of many suitable terminal configurations for use in a multi-junction photovoltaic module according to the present disclosure; and

FIG. 6 is a schematic illustration of a multi-junction photovoltaic module according to an alternative embodiment of the present disclosure.

### DETAILED DESCRIPTION

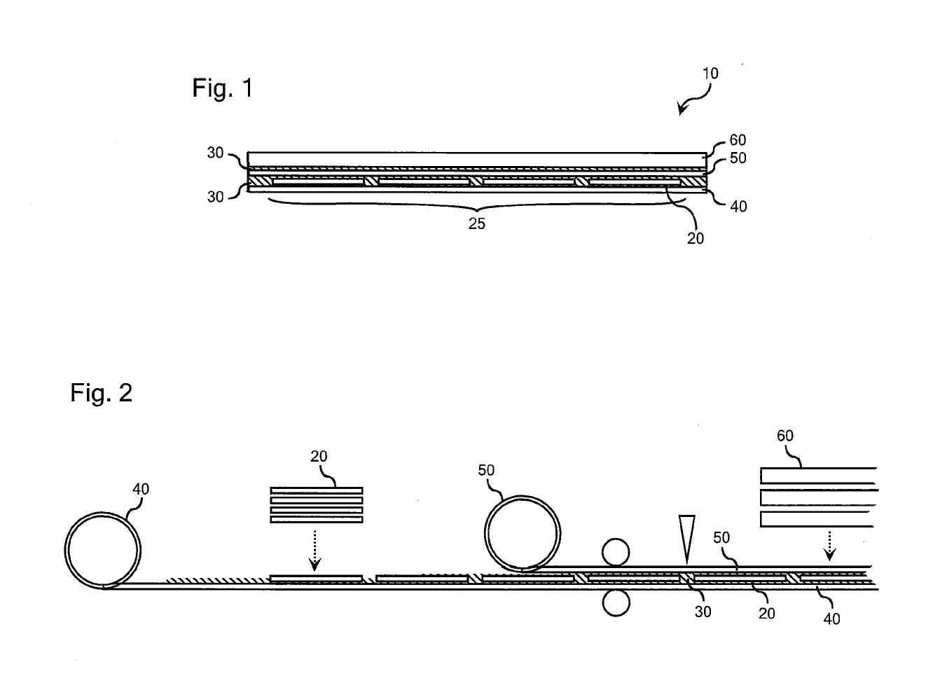

A photovoltaic module 10 according to one embodiment of the present invention is illustrated schematically in FIG. 1 and comprises a plurality of photovoltaic wafers 20, a wafer encapsulant 30, an encapsulating glass substrate 40, an encapsulating glass superstrate 50, and a structural glass layer 60. The photovoltaic wafers 20 define an active area 25 of the photovoltaic module 10 and are at least partially surrounded by the wafer encapsulant 30 between the encapsulating glass substrate 40 and the encapsulating glass superstrate 50.

The encapsulating glass substrate 40 and the encapsulating glass superstrate 50 can comprise UTF specialty glass and, as such, are less than approximately 2.0 mm in thickness across a substantial entirety of the active area 25 of the photovoltaic module 10 and define a degree of flexibility that is sufficient for non-destructive storage in a roll form. The respective glass compositions of the encapsulating glass substrate 40 and the encapsulating glass superstrate 50 can be derived from a variety of conventional and yet-to-be developed UTF specialty glasses, with the restriction that suitable glasses will be substantially Na-free, defined herein as comprising no more than approximately 1 weight % Na. For example, and not by way of limitation, suitable UTF specialty glasses comprise alumino and boro-silicate glasses. The resulting module 10 is highly hermetic and thus resistant to water ingress, can be extremely light weight, and can be scaled to larger size formats without exceeding typical installation weight limits.

The structural glass layer 60 is, for example, a Na-based glass, which may be defined as comprising more than approximately 1 weight % Na, and has a thickness and rigidity greater than that of the encapsulating glass substrate 40 and the encapsulating glass superstrate 50. The structural glass layer 60 can be secured directly to the encapsulating glass superstrate 50 and, as such, defines a PV structure-free zone between it and the superstrate 50.

In the illustrated embodiment, the photovoltaic wafers 20 are separated from the structural glass layer 60 by the encapsulating glass superstrate 50 to form a Na migration barrier between the structural glass layer 60 and the photovoltaic wafers 20. However, it is contemplated that the photovoltaic wafers 20 can be separated from the structural glass layer 60 by the encapsulating glass substrate 40 or the encapsulating glass superstrate 50. In either case, the resulting impurity barrier will impede impurity migration from the structural glass layer 60 into the UTF-encapsulated portions of the module 10. Impurities could be, among other things, alkali metals that diffuse out of the strengthened structural glass and into the active device layers, and hence, degrade device performance. The resulting PV module 10 can be manufactured as a high efficiency thin-film module and presents a path to low cost PV modules that leverages both the packaging and manufacturing benefits of UltraThin Flexible (UTF) specialty glass.

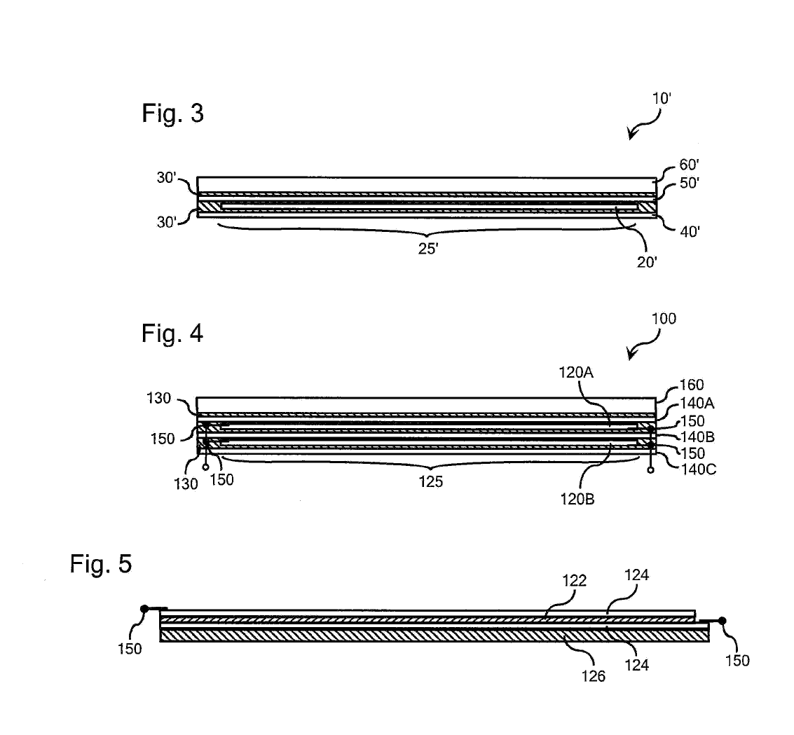

It is contemplated that the PV wafers 20 may be presented in a variety of forms including, but not limited to, wafered-Si, for example crystalline silicon, macrocrystalline silicon, microcrystalline silicon, or combinations thereof. Alternatively, as is illustrated in FIG. 3, where like structure is illustrated with like reference numbers, it is contemplated that the PV wafers 20 may be replaced by thin-film PV structure 20′ including, but not limited to, CdTe, Si-Tandem, a-Si, and copper indium gallium (di)selenide (CIGS) thin film structures. Although the concepts of the present disclosure are described herein primarily in the specific context of PV wafers 20, as opposed to thin-film or other PV technology, it is noted that reference herein to PV structure is intended to encompass a variety of PV applications including, but not limited to PV wafers and thin-film PV structure.

In some embodiments of the present disclosure, the encapsulating glass substrate 40 and the encapsulating glass superstrate 50 are selected to define a degree of flexibility that is sufficient to mitigate increases in module thickness arising from topography variations between the encapsulating glass substrate 40 and the encapsulating glass superstrate 50. For example, individual sheets of CIGS cells on UTF specialty glass can be assembled using a commercially available encapsulant material (such as EVA, PVB, ionomer, etc) and standard PV module lamination equipment and techniques. Typical sheets of encapsulant material are 0.5 mm thick and allow for some topography variation in the adjoining glass sheets. The flexibility of the UTF specialty glass substrate 40 and superstrate 50 provide a means to further conform to small deviations in flatness between the substrate 40 and superstrate 50 and thus enables the use of a thinner (0.25 mm or thinner) encapsulant sheet, further reducing module costs.

For example, in particular contemplated embodiments of the present disclosure, the degree of flexibility of the encapsulating glass substrate and the encapsulating glass superstrate will be sufficient for self-weighted, substantially failure-free (less than 1% failure probability) bending at a bend radius of less than approximately 100 cm. In more limited cases, where flexibility is a primary concern, it is contemplated that the degree of flexibility of the encapsulating glass substrate and the encapsulating glass superstrate will be sufficient for self-weighted, substantially failure-free bending at a bend radius of less than approximately 30 cm.

Although we note above that UTF specialty glasses are typically less than approximately 0.7 mm thick and, more generally, less than approximately 2.0 mm in thickness across a substantial entirety of the active area 25 of the photovoltaic module 10, it is contemplated that preferred embodiments will typically utilize encapsulating glass substrates 40 and encapsulating glass superstrates 50 that are between approximately 0.05 mm and approximately 0.3 mm in thickness across the substantial entirety of the active area 25 of the photovoltaic module 10. In many embodiments, it is contemplated that preferred substrate and superstrate thicknesses will be less than or equal to approximately 0.3 mm. It is contemplated that, in many cases, it may be preferable to use different thicknesses for the superstrate and substrate glasses to optimize the overall strength of the final assembly and minimize cost.

In many cases, it will be preferably to further enhance operational efficiency and minimize device degradation by ensuring that the respective glass compositions of the encapsulating glass substrate and the encapsulating glass superstrate are substantially Alkali-free. Further, it is contemplated that it may be preferable to ensure that the respective glass compositions of the encapsulating glass substrate 40 and the encapsulating glass superstrate 50 are characterized by respective coefficients of thermal expansion matching that of the photovoltaic wafers—at least over an operating temperature range of the photovoltaic module, i.e., from about −45° C. to about 150° C. This CTE match can enable the use of very thin Si wafers to minimize cost. The CTE match could also enable the elimination of one encapsulant layer, most likely the layer between the wafers and substrate UTF glass to reduce manufacturing complexity and cost.

In many cases, the structural glass layer 60 will comprise a soda-lime glass composition. However, it is contemplated that the structural glass layer 60 may be generally viewed as high transmission, strengthened structural glass, like tempered, low-Fe soda-lime glass, or any structural glass suitable for the formation of a readily deployable UTF specialty glass-based wafered-Si module.

FIG. 2 is a schematic illustration of contemplated methods of fabricating photovoltaic modules according to the present disclosure. As we note above, contemplated PV modules will typically comprise a plurality of photovoltaic wafers 20, a wafer encapsulant 30, an encapsulating glass substrate 40, an encapsulating glass superstrate 50, and a structural glass layer 60. According to the fabrication process the encapsulating glass substrate 40 and superstrate 50 are provided in rolled form. A plurality of photovoltaic wafers 20 are positioned over an unrolled portion of the encapsulating glass substrate 40 to define the active area of the photovoltaic module. The photovoltaic wafers 20, so positioned, are encapsulated with the wafer encapsulant 30 and an unrolled portion of the encapsulating glass superstrate 50 is positioned over the photovoltaic wafers 20, the wafer encapsulant 30, and the encapsulating glass substrate 40. Subsequently, the structural glass layer 60 is positioned over the encapsulating glass superstrate 50. The fabrication process further comprises a dicing operation, illustrated schematically at 70 in FIG. 2, where discrete module subassemblies are created prior to positioning the structural glass layer 60 over the encapsulating glass superstrate.

It is contemplated that the technology of the present disclosure can be employed to configure a parallel PV stacked cell circuit, where the photovoltaic structures of the module are arranged in parallel via dedicated circuit nodes such that electrical current generated in the photovoltaic structures is collected in the parallel PV stacked cell circuit. In this manner, those practicing the concepts of the present disclosure may use UTF specialty glass to stack compactly a series of two-terminal PV junctions that allow the optical to electrical conversion of a broad spectral range of the solar spectrum without the need to current match the individual junctions—as is the case for monolithically stacked junctions like a Si-Tandem dual junction cell.

It is also contemplated that the technology of the present disclosure can be employed to configure a serial PV stacked cell circuit, where the photovoltaic structures of the module are arranged in series via dedicated circuit connections between cells such that electrical voltage generated in the photovoltaic structures is collected in the serial PV stacked cell circuit. In this manner, those practicing the concepts of the present disclosure may use UTF specialty glass to stack compactly a series of two-terminal PV junctions that allow the optical to electrical conversion of a broad spectral range of the solar spectrum without the need to voltage match the individual junctions.

For example, and not by way of limitation, a multi junction photovoltaic module 100 is illustrated in FIG. 4 and comprises a plurality of photovoltaic structures 120A, 120B, circuit nodes 150 coupled to the plurality of photovoltaic structures, a PV encapsulant 130, a plurality of encapsulating glass layers 140A, 140B, 140C, and a structural glass layer 160. The principles of operation of a multi-junction photovoltaic cell can be readily gleaned from available art like, for example, U.S. Pat. Nos. 7,122,733 and 7,863,515. For the purposes of the present disclosure it will be sufficient to note that the photovoltaic structures 120A, 120B define distinct absorption bands, which may overlap or lie in exclusive portions of the solar spectrum. Further, the photovoltaic structures 120A, 120B are positioned with the encapsulating glass layers 140A, 140B, 140C and the structural glass layer 160 along a common incident solar radiation path of the module 100, which path may extend along a variety of directions across the cell structure of the module. It is also worth noting that the photovoltaic structures 120A, 120B may define overlapping or congruent positions along the common incident solar radiation path and that the module may be designed to receive incident solar radiation from either or both sides of the cell structure, depending upon the particular configuration selected for the module 100.

In any case, the photovoltaic structures 120A and 120B can be presented as PV wafers or PV thin films, as discussed above, and can be said to define an active area 125 of the photovoltaic module 100. In the illustrated embodiment, the photovoltaic structures 120A and 120B are surrounded by the PV encapsulant 130 and are separated by respective encapsulating glass layers 140A, 140B, 140C to electrically isolate adjacent photovoltaic structures and permit the photovoltaic structures to be configured in a parallel or serial PV stacked cell circuit. The general structure of one of the many types of suitable thin film photovoltaic structures is presented schematically in FIG. 5 to help illustrate the manner in which the control nodes 150 can be interfaced with the various layers of a photovoltaic structure. Specifically, FIG. 5 illustrates a thin film photovoltaic structure comprising an active layer 122 sandwiched between pair of transparent conductive electrodes 124, all of which are formed over a substrate 126, which may comprise an encapsulant and an encapsulating glass layer. Each control node 150 is electrically coupled to opposite sides of the thin film active layer 122 to encourage the flow of photovoltaic current. Each PV cell wired in this manner can be coupled in parallel or serial with other similarly wired cells.

As noted above with reference to the embodiments of FIGS. 1-3, the encapsulating glass layers 140A, 140B, 140C, which are described above as encapsulating glass substrates/superstrates, are typically less than approximately 2.0 mm in thickness and define a degree of flexibility that is sufficient for non-destructive storage in roll form. The structural glass layer 160 is also described above with reference to FIGS. 1-3 and, as we note above, typically has a thickness and rigidity greater than that of the encapsulating glass layers 140A, 140B, 140C.

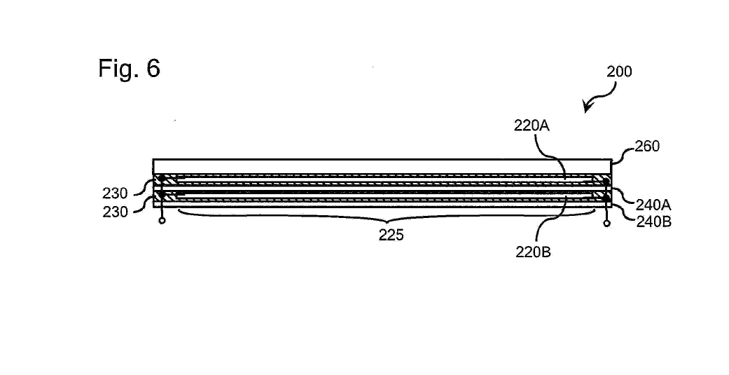

Referring finally to FIG. 6, the photovoltaic module 200 of this alternative embodiment also comprises a plurality of photovoltaic structures 220A, 220B, a PV encapsulant 230, a plurality of encapsulating glass layers 240A, 240B, and a structural glass layer 260 but lacks the additional encapsulating glass layer between the structural glass layer 260 and the directly adjacent photovoltaic structures 220A. This embodiment is presented to help illustrate that it may not be necessary or preferred in all embodiments to form a migration barrier between the structural glass layer 260 and the directly adjacent photovoltaic structures 220A, even where the structural glass layer is a Na-based glass.

For the purposes of describing and defining the present invention, it is noted that reference herein to a variable being a “function” of a parameter or another variable is not intended to denote that the variable is exclusively a function of the listed parameter or variable. Rather, reference herein to a variable that is a “function” of a listed parameter is intended to be open ended such that the variable may be a function of a single parameter or a plurality of parameters.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the terms “substantially” and “approximately” are utilized herein to represent the inherent degree of uncertainty that may be attributed to any quantitative comparison, value, measurement, or other representation. The terms “substantially” and “approximately” are also utilized herein to represent the degree by which a quantitative representation may vary from a stated reference without resulting in a change in the basic function of the subject matter at issue.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

What is claimed is:

1. A multi-junction photovoltaic module comprising a plurality of photovoltaic structures, a PV encapsulant, a plurality of encapsulating glass layers, and a structural glass layer, wherein:
the photovoltaic structures define distinct absorption bands and are positioned with the encapsulating glass layers and the structural glass layer along a common incident solar radiation path of the module;
the photovoltaic structures define an active area of the photovoltaic module and are at least partially surrounded by the PV encapsulant;
the photovoltaic structures are separated by respective encapsulating glass layers to electrically isolate adjacent photovoltaic structures and permit the photovoltaic structures to be configured in a parallel or a serial PV stacked cell circuit;
the encapsulating glass layers are less than approximately 2.0 mm in thickness and define a degree of flexibility that is sufficient for non-destructive storage in roll form; and
the structural glass layer has a thickness and rigidity greater than that of the encapsulating glass layers.

2. The photovoltaic module of claim 1, wherein:
the module further comprises circuit nodes coupled to the plurality of photovoltaic structures; and
the photovoltaic structures are arranged in the parallel PV stacked cell circuit via the circuit nodes such that electrical current generated in the photovoltaic structures is collected in the parallel PV stacked cell circuit.

3. The photovoltaic module of claim 1, wherein:
the module further comprises circuit connections coupling at least two photovoltaic structures; and
the photovoltaic structures are arranged in the serial PV stacked cell circuit via the circuit connections such that electrical voltage generated in the photovoltaic structures is collected in the serial PV stacked cell circuit.

4. The photovoltaic module of claim 1, wherein at least one of the photovoltaic structures is positioned between two encapsulating glass layers to form a migration barrier about the photovoltaic structure.

5. The photovoltaic module of claim 1, wherein:
the glass composition of the encapsulating glass layers are substantially Na-free;
the structural glass layer is a Na-based glass; and
at least one of the photovoltaic structures is separated from the structural glass layer by an encapsulating glass layer to form a Na migration barrier between the structural glass layer and the photovoltaic structure.

6. The photovoltaic module of claim 1, wherein the distinct absorption bands lie in overlapping or exclusive portions of the solar spectrum.

7. The photovoltaic module of claim 1, wherein the photovoltaic structures define overlapping or congruent positions along the common incident solar radiation path of the module.

8. The photovoltaic module of claim 1 wherein the encapsulating glass layers define a degree of flexibility that is sufficient to mitigate increases in module thickness arising from topography variations between the encapsulating glass substrate and the encapsulating glass superstrate.

9. The photovoltaic module of claim 1, wherein the degree of flexibility of the encapsulating glass layers is sufficient for self-weighted, substantially failure-free bending at a bend radius of less than approximately 100 cm.

10. The photovoltaic module of claim 1, wherein the encapsulating glass layers are less than approximately 2.0 mm in thickness across a substantial entirety of the active area of the photovoltaic module.

11. The photovoltaic module of claim 1, wherein the encapsulating glass layers are between approximately 0.05 mm and approximately 2.0 mm in thickness across a substantial entirety of the active area of the photovoltaic module.

12. The photovoltaic module of claim 1, wherein the encapsulating glass layers are less than or equal to approximately 0.3 mm in thickness across a substantial entirety of the active area of the photovoltaic module.

13. The photovoltaic module of claim 1, wherein the respective glass compositions of the encapsulating glass layers are substantially Alkali-free.

14. The photovoltaic module of claim 1, wherein the respective glass compositions of the encapsulating glass layers are characterized by a coefficient of thermal expansion matching that of the photovoltaic structure over an operating temperature range of the photovoltaic module.

15. The photovoltaic module of claim 1, wherein the composition of the structural glass layer is a soda-lime glass composition.

16. The photovoltaic module of claim 1, wherein the solar radiation path extends linearly or non-linearly across a stack of the plurality of photovoltaic structures.

17. The photovoltaic module of claim 1, wherein the photovoltaic structure is secured to an associated encapsulating glass layer via a PV encapsulant there between.

18. The photovoltaic module of claim 1, wherein the PV encapsulant comprises EVA, PVB, an ionomer, or a combination thereof.

19. The photovoltaic module of claim 1, wherein the photovoltaic structure comprises a plurality of PV wafers.

20. The photovoltaic module of claim 1, wherein the photovoltaic structure comprises a thin-film photovoltaic structure selected from CdTe, Si-Tandem, a-Si, and copper indium gallium (di)selenide (CIGS) thin film structures.

21. A multi-junction photovoltaic module comprising a plurality of photovoltaic structures, a PV encapsulant, a plurality of encapsulating glass layers, and a structural glass layer, wherein:
the photovoltaic structures define distinct absorption bands and are positioned with the encapsulating glass layers and the structural glass layer along a common incident solar radiation path of the module;
the photovoltaic structures define an active area of the photovoltaic module and are at least partially surrounded by the PV encapsulant;
the photovoltaic structures are separated by respective encapsulating glass layers to electrically isolate adjacent photovoltaic structures and permit the photovoltaic structures to be configured in a parallel or a serial PV stacked cell circuit;
the module further comprises circuit nodes coupled to the plurality of photovoltaic structures or comprises circuit connects to at least two of the photovoltaic structures;
the photovoltaic structures are arranged in the parallel PV stacked cell circuit via the circuit nodes such that electrical current generated in the photovoltaic structures is collected in the parallel PV stacked cell circuit or the photovoltaic structures are arranged in the serial PV stacked cell circuit via the circuit connections such that electrical voltage generated in the photovoltaic structures is collected in the serial PV stacked cell circuit;
the encapsulating glass layers are less than approximately 2.0 mm in thickness and define a degree of flexibility that is sufficient for non-destructive storage in roll form;
the structural glass layer has a thickness and rigidity greater than that of the encapsulating glass layers;
the glass composition of the encapsulating glass layers are substantially Na-free;
the structural glass layer is a Na-based glass; and
one of the photovoltaic structures is separated from the structural glass layer by an encapsulating glass layer to form a Na migration barrier between the structural glass layer and the photovoltaic structure.
